(19) United States
(12) Patent Application Publication
(10) Pub. No.: US 2004/0141461 A1
(43) Pub. Date: Jul. 22, 2004

(54) Remote reset using a one-time pad

(76) Inventors: Vincent J. Zimmer, Federal Way, WA (US); Michael A. Rothman, Gig Harbor, WA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/349,892

(22) Filed: Jan. 22, 2003

(51) Int. Cl. G01R 31/08

(52) U.S. Cl. 370/216

(57) ABSTRACT

A method for enabling a manageability server or host to remotely reset a hung computer or machine on a network. A target platform is provisioned. Provisioning of the target platform includes generating a different secure code for each computer on the network and enabling each computer to store the secure code in non-volatile memory. The manageability server monitors the computers on the network to determine whether a foreground environment of each of-the computers is responsive. If any of the computers on the network are not responsive, the manageability server sends a special packet to each of the non-responsive computers. The special packet may be a Wake-on-LAN packet. After sending the special packet, the manageability server sends a reset request packet to each of the non-responsive computers for enabling each non-responsive computer to be reset. The reset request packet includes the secure code. The secure code from the reset request packet must match the secure code stored on the non-responsive computers before the non-responsive computer may be reset. The secure code may be a one-time pad (OTP).

### BACKGROUND OF THE INVENTION

1. Field of the Invention

The present invention is generally related to network management. More particularly, the present invention is related to a mechanism and method for remotely resetting a hung machine.

2. Description

A fundamental business practice is controlling costs. An area where companies fall short in controlling costs is in managing information technology (IT) assets. For example, when companies purchase a set of computers, each computer costs a fixed amount. However, during the life cycle of the computer, the amount of the investment changes. For example, after computers are purchased, computer support configures each machine with the appropriate settings to enable the machine to work in the company's network environment. Computer support also installs the appropriate software and other peripheral devices according to the needs of the department in which the computers will be used. Configuring the computer along with the installation of software and other peripheral devices increases the value of the computer.

In many instances, costs incurred to maintain a computer on a yearly basis exceed the original purchase price of the computer. Maintenance costs may include but are not limited to, installing operating system updates, performing system management routines, transferring files, tracking inventory or assets, sending a technician to repair failed hardware, etc.

Thus, the purchase price of the computer and the costs incurred during the life cycle of the computer represent the total cost of ownership or TCO. To ameliorate some of the TCO expenses, companies are moving towards implementing manageability features into their basic input/output systems (BIOS) and platform chipsets. For example, a standard called system management bios is used to provide an operating system with an inventory of what components are plugged into a client PC, how much memory is available on the PC, and whether there are any failures with the PC.

Another manageability feature is Wake-on-LAN (local-area network) (WoL). WoL allows a computer on a network, such as, for example, a local-area network (LAN), a wide-area network (WAN), an Intranet, and possibly the Internet, to be remotely turned on to perform various tasks. The need for an individual to be physically located at the computer to turn the computer on is eliminated. This enables various tasks to be performed when traffic is slower and when most people are not at work, such as after work hours or on weekends. The tasks performed may include, but are not limited to, updating PCs and workstations with new drivers and/or software, performing management asset programs, etc.

A problem that may cause the TCO to increase is the hung computer or the hung machine. Often times a foreground operating system of the computer may encounter a catastrophic error that prevents the computer from being able to shut down properly. In other words, the computer is hung and will not shut down properly. For example, as a result of the latest network driver or video driver being installed, a catastrophic error occurs such that the operating system kernel may not be able to alert the user and/or shut down the computer.

Thus, what is needed is a manageability feature that allows an agent, outside of the hung computer (or hung machine), on the network to detect that the hung computer (or hung machine) is non-responsive and remotely reset the hung computer.

### BRIEF DESCRIPTION OF THE DRAWINGS

The accompanying drawings, which are incorporated herein and form part of the specification, illustrate embodiments of the present invention and, together with the description, further serve to explain the principles of the invention and to enable a person skilled in the pertinent art(s) to make and use the invention. In the drawings, like reference numbers generally indicate identical, functionally similar, and/or structurally similar elements. The drawing in which an element first appears is indicated by the leftmost digit(s) in the corresponding reference number.

FIG. 1 is a block diagram illustrating an exemplary local-area network (LAN) in which embodiments of the present invention may be implemented.

FIG. 2 is a block diagram illustrating an exemplary wide-area network (WAN) in which embodiments of the present invention may be implemented.

FIG. 3 is a flow diagram describing a method for a manageability server or host to enable the remote reset of a hung computer according to an embodiment of the present invention.

FIG. 4 is a flow diagram describing a system management mode method for remotely resetting a hung machine according to an embodiment of the present invention.

FIG. 5 is a block diagram illustrating an exemplary computer system in which certain aspects of the invention may be implemented.

### DETAILED DESCRIPTION OF THE INVENTION

While the present invention is described herein with reference to illustrative embodiments for particular applications, it should be understood that the invention is not limited thereto. Those skilled in the relevant art(s) with access to the teachings provided herein will recognize additional modifications, applications, and embodiments within the scope thereof and additional fields in which embodiments of the present invention would be of significant utility.

Reference in the specification to “one embodiment”, “an embodiment” or “another embodiment” of the present invention means that a particular feature, structure or characteristic described in connection with the embodiment is included in at least one embodiment of the present invention. Thus, the appearances of the phrase “in one embodiment” appearing in various places throughout the specification are not necessarily all referring to the same embodiment.

Embodiments of the present invention are directed to a mechanism and method for remotely resetting one or more computers in a network when one or more of the computers are hung up, or in other words, stop responding to a manageability host computer. This is accomplished using a commodity network interface controller (NIC) with a standard packet based mechanism to engender an event on a target platform. A Wake-on-LAN (local-area network) (WoL) event is used to generate a system management interrupt (SMI). An ensuing packet, referred to as the reset request packet, shall be encoded with a secret specific to the packet. The secret specific to the packet may only be shared between the manageability host and a client. If a foreground environment, such as, but not limited to, Microsoft® Windows® XP Operating System (manufactured by Microsoft Corporation), on the client ceases to respond to the manageability host, the WoL event is issued to the client. The reset request is sent to the client with the secret specific to the platform. If the secret specific to the platform matches the secret at the client, the client is reset using peripheral component interface (PCI) reset hardware.

Embodiments of the present invention are described as being implemented in local-area networks (LANs) as well as wide-area networks (WANs). One skilled in the relevant art(s) would know that other network environments, such as, but not limited to, Intranets and the Internet, are equally applicable.

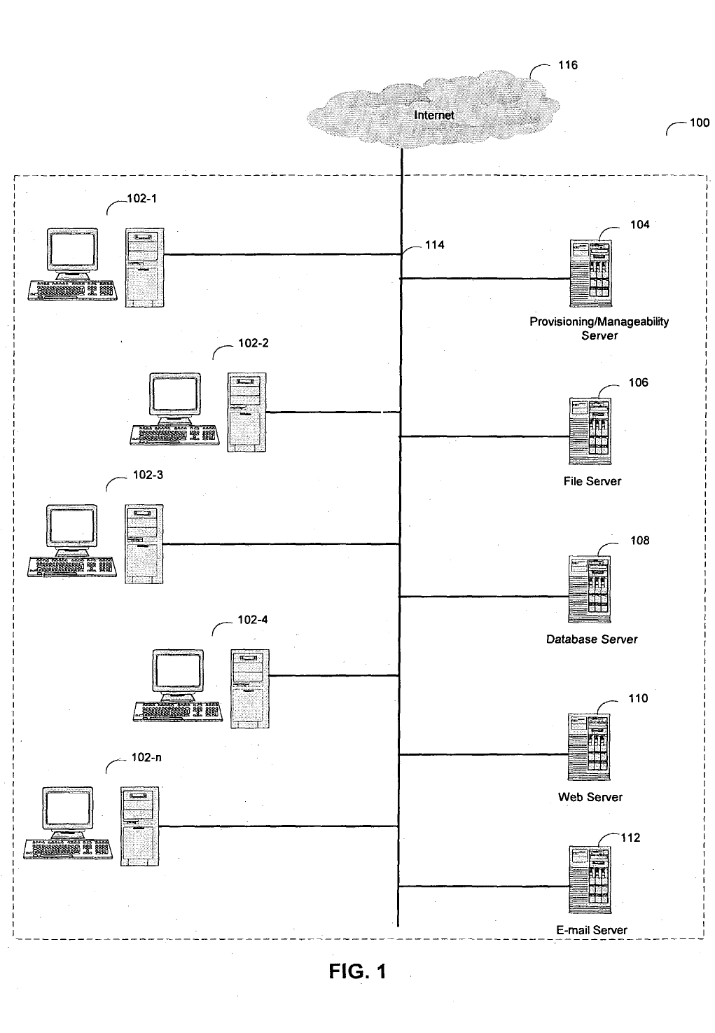

FIG. 1 is a block diagram illustrating an exemplary LAN network 100 (shown in phantom) in which embodiments of the present invention may be implemented. LAN networks, such as LAN network 100, span a relatively small area, and in many instances, may be confined to one building or a group of buildings.

LAN network 100 comprises, inter alia, a plurality of workstations 102-1 . . . 102-n and a plurality of servers (104, 106, 108, 110, and 112) connected together via a bus topology 114. Other network topologies, such as a star and a ring topology, may be used as well.

Workstations 102-1 . . . 102-n are electronic computing devices. Each workstation 102-1 . . . 102-n comprises, inter alia, at least one processor and other associated circuitry, such as memory, a network interface card, one or more data storage units, etc. Workstations 102-1 . . . 102-n also include a high resolution graphics display, such as a cathode ray tube (CRT) display or liquid crystal display (LCD), and input/output means, such as, but not limited to, a keyboard. Workstations 102-1 . . . 102-n may be single-user or multiple-user computers for accepting, processing, storing, and outputting data at high speeds according to programmed instructions. In the networking environment, workstations are known as any computer connected to a local-area network. This may include a workstation or a personal computer, such as a desktop or laptop computer.

As previously stated above, LAN network 100 includes a plurality of servers (104, 106, 108, 110, and 112) for managing network resources. Such servers include a provisioning/manageability server 104, a file server 106, a database server 108, a Web server 110, and an electronic mail (e-mail) server 112. Although not shown, other types of servers, such as print servers, applications servers, etc., may also be included in LAN network 100.

Provisioning/manageability server 104 is a computer system used to manage LAN network 100. Network management may include, but is not limited to, creating a boot diskette for a new user on one of workstations 102-1 . . . 102-n and making sure that the new user has proper access to network resources; daily disk maintenance duties, such as backing up network files and defragmenting disk directories; troubleshooting LAN network 100; reconfiguring a remote internetwork device to improve overall system performance, etc. In short, provisioning/manageability server 104 is responsible for keeping LAN network 100 running smoothly and efficiently to minimize downtime.

Provisioning/manageability server 104 is also used to provide manageability features for managing IT assets. For example, in an embodiment of the present invention, server 104 may be used to remotely reset one or more of workstations 102-1 . . . 102-n and/or servers 106, 108, 110, and 112, which is described in detail below.

File server 106 enables network users to share computer programs and data. Thus, file server 106 acts as a storage device for enabling any user on the network to store files.

Database server 108 is a computer system that processes queries. Database server 108 is comprised of a database application. The database application is divided into two parts. A first part, which runs on a user's computer (e.g., workstations 102-1 . . . 102-n), displays the data and interacts with the user. A second part, which runs on database server 108, preserves data integrity and handles most of the processor-intensive work, such as data storage and manipulation.

LAN network 100 is connected to the Internet 116 to enable users of LAN network 100 to browse the Internet 116 using Web server 110 and communicate with users on other networks via electronic mail using E-mail server 112. Web server 110 is a computer system that delivers or serves up Web pages to a browser for viewing by a user. Web server 110 stores HTML (hypertext markup language) documents in order for users to access the documents on the Web. E-mail server 112 is a computer system for moving and storing electronic mail over networks such as LANs, WANs, and the Internet.

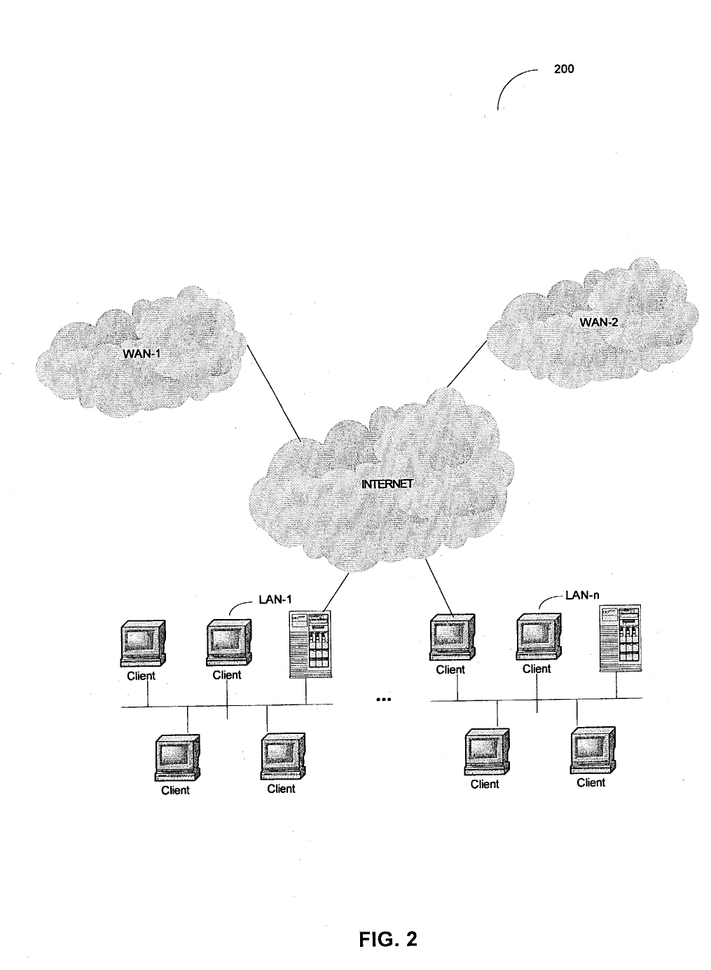

As previously stated, embodiments of the present invention may also be implemented in WANs as well. WANs are comprised of computer networks that span a relatively large geographical area. FIG. 2 is a block diagram illustrating an exemplary wide-area network (WAN) 200. As can be seen from FIG. 2, WAN 200 is comprised of a plurality of LANs (LAN-1 . . . LAN-n), WAN-1, WAN-2, and the Internet, which is also a wide-area network. WAN-1 and WAN-2 are comprised of a plurality of LANs (not shown). The computers connected to WAN 200 may be connected through public networks, such as a telephone system. They may also be connected through leased lines, satellites, or any other well known network connection means.

In WAN 200, a provisioning/manageability server on a LAN, such as LAN-1, may be able to reset a workstation or server on other LANs, WANs, and possibly the Internet using an embodiment of the present invention. In other words, a provisioning/manageability server on a particular network is not limited to resetting workstations and servers on that network alone, but may also be enabled to reset workstations and servers on other networks within WAN 200.

As previously stated, embodiments of the present invention are directed to a mechanism and method for remotely resetting a computer in a network environment in which the foreground environment is no longer responding to a manageability server (or host). The mechanism used is Wake-on-LAN (WoL). WoL technology works by sending a WoL packet to a client machine from a server that has remote network management capabilities. A CMOS (complementary metal-oxide semiconductor) process-based ASIC (Application Specific Integrated Circuit)/chipset component designed to use WoL technology is provided on the motherboard of the client machine. Also installed on the client machine is a network interface controller (NIC) for receiving the WoL packet. The WoL packet generates a system management interrupt that enables the processor of the client machine to transition into a system management mode (SMM) for executing system manageability code to reset the client machine.

By remotely resetting a hung computer, an automated method of failure recovery is implemented. The need for a service person to come and repair the hung computer may be eliminated.

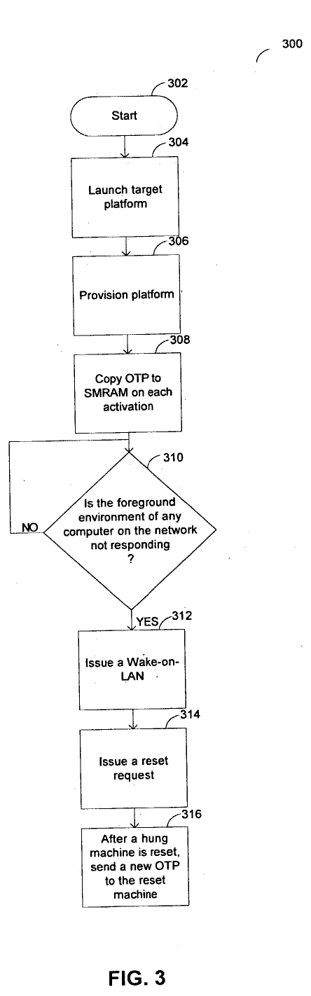

FIG. 3 is a flow diagram describing a method for a manageability server (or host) to enable the remote reset of a hung computer according to an embodiment of the present invention. The invention is not limited to the embodiment described herein with respect to flow diagram 300. Rather, it will be apparent to persons skilled in the relevant art(s) after reading the teachings provided herein that other functional flow diagrams are within the scope of the invention. The process begins with block 302, where the process immediately proceeds to block 304.

In block 304, a target platform is launched. This encompasses several tasks. Such tasks may include, but are not limited to, initiating the basic input/output system (BIOS), initializing main memory, starting up input/output (I/O) devices, and placing code into system management memory.

In block 306, the target platform is provisioned. In one embodiment, the provisioning agent may be a local application running on the provisioning/manageability server. In another embodiment, the provisioning agent may be a remote administrator. The provisioning process may be performed during pre-boot. In another embodiment, the provisioning process may be performed during operating system (OS) runtime.

During the provisioning process, a platform specific identity, such as a cryptographic public key, a system management basic input/output system (SMBIOS) globally unique identifier (GUID), etc. is obtained for each computer on the network managed by the provisioning/manageability (or host) server. Cryptographic public keys and SMBIOS GUIDs are well known to those skilled in the relevant art(s). The manageability server then generates for each computer a unique one-time pad (OTP) and sends it to each computer. Although embodiments of the present invention are described using the OTP, other types of secure encryption systems may be used, such as, but not limited to, asymmetric cryptography and public key infrastructure.

A one-time pad is an unconditionally secure encryption system. In other words, a one-time pad cannot be broken. A private (or secret) key, generated randomly, is used only once to encrypt a message that is then decrypted by the receiving entity using a matching one-time pad and secret key. Messages encrypted with keys based on true randomness prevent others from breaking the code. The use of an OTP prevents an inadvertent reset request packet from resetting a computer (or machine) that is operating normally. More importantly, the use of an OTP prevents a malicious agent or unauthorized party from having the ability to reset a computer. With the OTP, only the agent (ie., the manageability server or host) that generated the OTP is authorized to reset the hung computer.

In one embodiment of the present invention, a manageability server or host may periodically re-key the OTP. For example, the OTP may be re-keyed every hour, every four (4) hours, every eight (8) hours, every sixteen (16) hours, or every twenty-four (24) hours.

In block 308, each computer's firmware copies the computer's OTP to system management random access memory (SMRAM) each time the computer is activated normally so that a Wake-on-LAN handler can access its value. Alternatively, the OTP may be stored in flash memory, an EPROM, CMOS memory, or any other nonvolatile memory source. Storing the OTP in non-volatile memory enables successive user initiated restarts of the computer without compromising the ability to perform remote resets through the WoL mechanism.

In decision block 310, it is determined whether the foreground environment (such as, but not limited to, Microsoft® Windows® XP Operating System, manufactured by Microsoft Corporation) of any computer on the network is not responding to the provisioning/manageability server or manageability host. For example, a foreground operating system that was running on a client computer has now stopped running for some reason. The manageability server is unable to talk to the client computer. Note that the client computer may be a workstation, such as workstations 102-1 . . . 102-n, as well as a server, such as servers 106, 108, 110, and 112, on the network. If the foreground environment of any computer is not responding to the manageability server, then the computer that is not responding is referred to as the hung computer. If it is determined that a hung computer does not exist, the process remains at decision block 310 to continue tracking whether the foreground environment of any computer on the network is not responding. If it is determined that a hung computer does exist, the process proceeds to block 312.

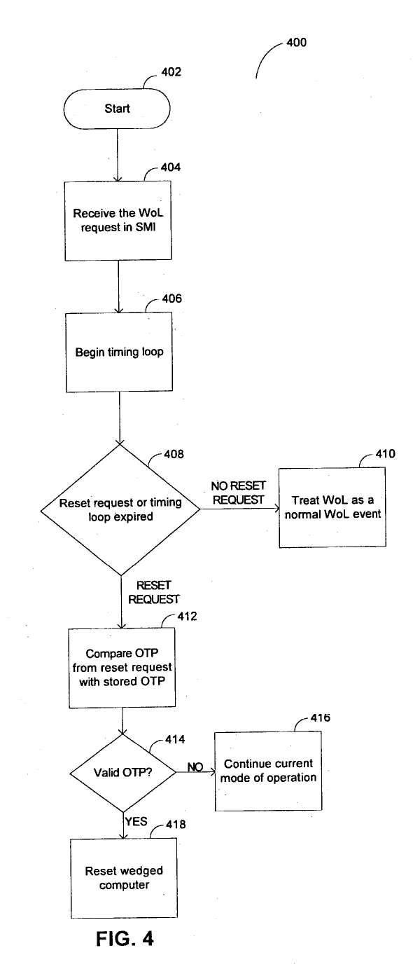

In block 312, a Wake-on-LAN (WoL) packet is issued to the hung computer via a network interface controller (NIC). The WoL packet generates a system management interrupt (SMI). The SMI in turn, transitions the processor into a system management mode (SMM). The SMM, owned exclusively by firmware and having protected memory, is decoupled from the foreground environment. SMM enables manageability code (or firmware) that, when executed, resets the hung computer. The SMM manageability code will be discussed below with reference to FIG. 4.

In an alternative embodiment, the network interface controller may provide the logic required to enable the hung computer to be reset. In this instance, the logic would be hardwired. For example, a state machine may be used to implement the logic of the SMM manageability code.

In block 314, a reset request packet, which includes the OTP, is issued. The reset request packet enables the hung computer to be reset. After the hung computer has been reset, a new OTP is issued to the reset computer in block 316. This is done to prevent the reuse of the OTP. Reuse of the one-time pad would be a violation of its purpose (i.e., to be used once) and may cause the OTP to lose its unbreakable properties.

FIG. 4 is a flow diagram 400 describing a system management mode (SMM) method for remotely resetting a hung computer (or machine) according to an embodiment of the present invention. The invention is not limited to the embodiment described herein with respect to flow diagram 400. Rather, it will be apparent to persons skilled in the relevant art(s) after reading the teachings provided herein that other functional flow diagrams are within the scope of the invention. The process begins with block 402, where the process immediately proceeds to block 404.

In block 404, the WoL packet is received by the hung computer. As previously stated, the WoL packet generates a system management interrupt (SMI) that, in turn, transitions the processor of the hung computer into a system management mode (SMM) for executing the following SMM manageability code.

In block 406, a timing loop begins. The timing loop is used to define the type of WoL event.

In decision block 408, it is determined whether the WoL event is a normal WoL event or a reset request event. If the timing loop expires prior to a reset request packet being received by the hung computer, the WoL event is treated as a normal WoL event (Block 410). If the timing loop does not expire before the reset request packet arrives, then the WoL event is a reset request event and the process proceeds to block 412.

In block 412, the OTP from the reset request packet is compared with the stored OTP. The comparison process is performed to determine whether the entity sending the reset request packet is a hostile entity or an entity to be trusted, namely, the entity that contains the secret to engender the reset. As previously stated, only the entity that generated the OTP (i.e., the manageability server) can reset the hung computer.

In one embodiment, when the OTP is sent via the reset request packet, it is encrypted with a secret key using an XOR operation to form ciphertext. Upon receipt of the ciphertext, the recipient (i.e., hung computer), having first hand knowledge of the OTP, will XOR the OTP with the ciphertext to obtain the secret key.

In decision block 414, it is determined whether the OTP received in the reset request packet is valid. If the secret key is correct, the OTP is valid, and the process proceeds to block 418.

In block 418, the hung computer is reset. In one embodiment, the reset is performed using peripheral component interface (PCI) reset hardware from an Application Specific Integrated Circuit (ASIC) or chipset. A particular byte sequence is sent to an I/O port on the ASIC that enables the ASIC to assert a reset signal to the processor and/or any other chips on the platform that require resetting. This resets the hung computer, enabling the computer to start over again and re-launch the operating system into a working environment. At this time, the operating system of the reset computer may communicate with the network again.

In one embodiment, the reset event is logged by recording the event into flash memory or some other type of persistent storage for conveying an accurate error log of the event to the manageability server or some other agent on the network. In one embodiment, this may occur prior to resetting the hung computer. In another embodiment, this may occur after the hung computer is reset.

Returning to decision block 414, if the secret key is not correct, the OTP is invalid. This may be an indication that the entity that sent the reset request packet is hostile and, therefore, is not allowed to enable a reset of the machine. This may also be an indication that the computer was not a hung computer (i.e., the computer did not need to be reset). The process then proceeds to block 416. In block 416, the current mode of operation is continued.

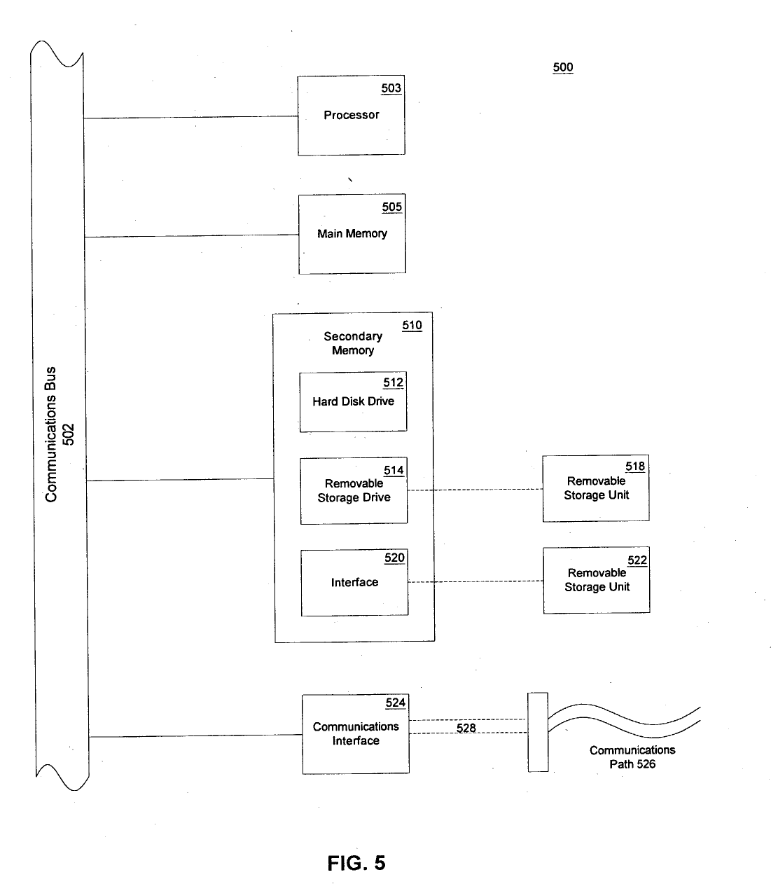

Embodiments of the present invention may be implemented using hardware, software, or a combination thereof and may be implemented in one or more computer systems or other processing systems. In fact, in one embodiment, the invention is directed toward one or more computer systems capable of carrying out the functionality described here. An example implementation of a computer system 500 is shown in FIG. 5. Various embodiments are described in terms of this exemplary computer system 500. After reading this description, it will be apparent to a person skilled in the relevant art how to implement the invention using other computer systems and/or computer architectures.

Computer system 500 includes one or more processors, such as processor 503. Processor 503 is capable of handling Wake-on-LAN technology. Processor 503 is connected to a communication bus 502. Computer system 500 also includes a main memory 505, preferably random access memory (RAM) or a derivative thereof (such as SRAM, DRAM, etc.), and may also include a secondary memory 510. Secondary memory 510 may include, for example, a hard disk drive 512 and/or a removable storage drive 514, representing a floppy disk drive, a magnetic tape drive, an optical disk drive, etc. Removable storage drive 514 reads from and/or writes to a removable storage unit 518 in a well-known manner. Removable storage unit 518 represents a floppy disk, magnetic tape, optical disk, etc., which is read by and written to by removable storage drive 514. As will be appreciated, removable storage unit 518 includes a computer usable storage medium having stored therein computer software and/or data.

In alternative embodiments, secondary memory 510 may include other similar means for allowing computer programs or other instructions to be loaded into computer system 500. Such means may include, for example, a removable storage unit 522 and an interface 520. Examples of such may include a program cartridge and cartridge interface (such as that found in video game devices), a removable memory chip (such as an EPROM (erasable programmable read-only memory), PROM (programmable read-only memory), or flash memory) and associated socket, and other removable storage units 522 and interfaces 520 which allow software and data to be transferred from removable storage unit 522 to computer system 500.

Computer system 500 may also include a communications interface 524. Communications interface 524 allows software and data to be transferred between computer system 500 and external devices. Examples of communications interface 524 may include a modem, a network interface (such as an Ethernet card), a communications port, a PCMCIA (personal computer memory card international association) slot and card, a wireless LAN (local area network) interface, etc. In one embodiment, communications interface 524 may be a network interface controller (NIC) capable of handling WoL technology. In this instance, when a WoL packet is received by communications interface 524, a system management interrupt (SMI) signal (not shown) is sent to processor 503 to begin the SMM manageability code for resetting computer 500. Software and data transferred via communications interface 524 are in the form of signals 528 which may be electronic, electromagnetic, optical or other signals capable of being received by communications interface 524. These signals 528 are provided to communications interface 524 via a communications path (i.e., channel) 526. Channel 526 carries signals 528 and may be implemented using wire or cable, fiber optics, a phone line, a cellular phone link, a wireless link, and other communications channels.

In this document, the term “computer program product” refers to removable storage units 518, 522, and signals 528. These computer program products are means for providing software to computer system 500. Embodiments of the invention are directed to such computer program products.

Computer programs (also called computer control logic) are stored in main memory 505, and/or secondary memory 510 and/or in computer program products. Computer programs may also be received via communications interface 524. Such computer programs, when executed, enable computer system 500 to perform the features of the present invention as discussed herein. In particular, the computer programs, when executed, enable processor 503 to perform the features of embodiments of the present invention. Accordingly, such computer programs represent controllers of computer system 500.

In an embodiment where the invention is implemented using software, the software may be stored in a computer program product and loaded into computer system 500 using removable storage drive 514, hard drive 512 or communications interface 524. The control logic (software), when executed by processor 503, causes processor 503 to perform the functions of the invention as described herein.

In another embodiment, the invention is implemented primarily in hardware using, for example, hardware components such as application specific integrated circuits (ASICs). Implementation of hardware state machine(s) so as to perform the functions described herein will be apparent to persons skilled in the relevant art(s). In yet another embodiment, the invention is implemented using a combination of both hardware and software.

While various embodiments of the present invention have been described above, it should be understood that they have been presented by way of example only, and not limitation. It will be understood by those skilled in the art that various changes in form and details may be made therein without departing from the spirit and scope of the invention as defined in the appended claims. Thus, the breadth and scope of the present invention should not be limited by any of the above-described exemplary embodiments, but should be defined in accordance with the following claims and their equivalents.

What is claimed is:

1. A method for a manageability server to enable failure recovery comprising:
provisioning a target platform, wherein provisioning the target platform comprises generating a different secure code for each one of a plurality of computers on a network and enabling each computer to store the secure code in non-volatile memory;
determining whether a foreground environment of each of the computers on the network is responsive; and
if any of the computers are not responsive,
sending a special packet to each of the non-responsive computers; and
sending a reset request packet to each of the non-responsive computers for enabling each non-responsive computer to be reset, wherein the reset request packet includes the secure code.

2. The method of claim 1, wherein the plurality of computers comprises at least one of workstations, desktop computers, laptop computers, and server computers.

3. The method of claim 1, further comprising launching the target platform prior to provisioning the target platform.

4. The method of claim 3, wherein launching the target platform comprises initiating a basic input/output system (BIOS), initializing main memory, starting up input/output (I/O) devices, and placing code into system management memory.

5. The method of claim 1, wherein the special packet comprises a Wake-on-LAN (local-area network) (WoL) packet.

6. The method of claim 1, wherein provisioning the target platform comprises provisioning the target platform during pre-boot operations.

7. The method of claim 1, wherein provisioning the target platform comprises provisioning the target platform during operating system runtime.

8. The method of claim 1, wherein provisioning the target platform further comprises receiving a platform specific identity for each computer on the network.

9. The method of claim 8, wherein the platform specific identity comprises one of a cryptographic public key and a system management basic input/output system (SMBIOS) globally unique identifier (GUID).

10. The method of claim 1, wherein the secure code comprises a one-time pad (OTP).

11. The method of claim 10, further comprising re-keying the one-time pad for each computer on the network periodically.

12. The method of claim 1, further comprising sending a new one-time pad to the non-responsive computer after the non-responsive computer has been reset.

13. The method of claim 1, wherein a provisioning agent used to provision the target platform comprises a local application.

14. A method for enabling a remote reset, comprising:
receiving a special packet from a manageability server, wherein the special packet generates an interrupt that transitions a processor of a hung computer into a management mode, the management mode enabling the hung computer to reset itself, the management mode method comprising,
determining whether the special packet indicates a reset request event;
if the special packet indicates a reset request event, receiving a reset request packet, wherein the reset request packet includes a secure code;
comparing the secure code with a stored secure code; and
if the secure code is valid, resetting the hung computer.

15. The method of claim 14, further comprising continuing a mode of operation performed prior to the interrupt, if the secure code is invalid.

16. The method of claim 14, wherein the special packet comprises a Wake-on-LAN (local-area network) packet.

17. The method of claim 14, wherein the secure code comprises a one-time pad (OTP).

18. The method of claim 17, wherein the one-time pad is encrypted with a secret key prior to being received, and wherein comparing the secure code with the stored secure code comprises decrypting the secure code to obtain the secret key.

19. The method of claim 14, wherein the hung computer comprises a computer in which a foreground operating system is non-responsive.

20. The method of claim 19, wherein a computer comprises one of a workstation, a desktop computer, a laptop computer, and a server computer.

21. The method of claim 14, wherein resetting the hung computer comprises sending a byte sequence for asserting a reset signal from an input/output port of a circuit to the processor, wherein the reset signal re-launches an operating system of the hung computer into a working environment.

22. The method of claim 21, wherein the circuit comprises an application specific integrated circuit (ASIC).

23. The method of claim 14, wherein resetting the hung computer further comprises recording the reset event in a persistent storage to generate an error log.

24. A system for enabling failure recovery, comprising:
at least one server for managing a plurality of computers on a network, each of the computers comprising
a motherboard designed to handle Wake-on-LAN (local-area network) (WoL) technology; and
a network interface controller (NIC) for receiving a WoL packet;
wherein the at least one server generates a different secure code for each of the plurality of computers on the network; and
wherein the at least one server monitors the plurality of computers to determine whether a foreground operating system on any one of the plurality of computers is non-responsive and sends the WoL packet and a reset request packet to any of the computers that are non-responsive to enable the non-responsive computers to reset themselves.

25. The system of claim 24, wherein the plurality of computers comprises clients and servers.

26. The system of claim 24, wherein the reset request packet includes the secure code for comparison with a stored secure code on the non-responsive computer, wherein the non-responsive computer is reset only if the secure code matches the stored secure code.

27. The system of claim 24, wherein each of the plurality of computers on the network further comprises an application specific integrated circuit (ASIC) having a reset signal that when input with an appropriate byte sequence, enables the non-responsive computers to reset themselves.

28. An article comprising: a storage medium having a plurality of machine accessible instructions, wherein when the instructions are executed by a processor, the instructions provide for provisioning a target platform, wherein provisioning the target platform comprises generating a different secure code for each one of a plurality of computers on a network and enabling each computer to store the secure code in non-volatile memory;
determining whether a foreground environment of each of the computers on the network is responsive; and
if any of the computers are not responsive,
sending a special packet to each of the non-responsive computers; and
sending a reset request packet to each of the non-responsive computers for enabling each non-responsive computer to be reset, wherein the reset request packet includes the secure code.

29. The article of claim 28, wherein the plurality of computers comprises at least one of workstations, desktop computers, laptop computers, and server computers.

30. The article of claim 28, further comprising instructions for launching the target platform prior to provisioning the target platform.

31. The article of claim 30, wherein instructions for launching the target platform comprises instructions for initiating a basic input/output system (BIOS), initializing main memory, starting up input/output (I/O) devices, and placing code into system management memory.

32. The article of claim 28, wherein the special packet comprises a Wake-on-LAN (local-area network) (WoL) packet.

33. The article of claim 28, wherein instructions for provisioning the target platform comprises instructions for provisioning the target platform during pre-boot operations.

34. The article of claim 28, wherein instructions for provisioning the target platform comprises instructions for provisioning the target platform during operating system runtime.

35. The article of claim 28, wherein instructions for provisioning the target platform further comprises instructions for receiving a platform specific identity for each computer on the network.

36. The article of claim 35, wherein the platform specific identity comprises one of a cryptographic public key and a system management basic input/output system (SMBIOS) globally unique identifier (GUID).

37. The article of claim 28, wherein the secure code comprises a one-time pad (OTP).

38. The article of claim 37, further comprising instructions for re-keying the one-time pad for each computer on the network periodically.

39. The article of claim 28, further comprising instructions for sending a new one-time pad to the non-responsive computer after the non-responsive computer has been reset.

40. The article of claim 28, wherein a provisioning agent used to provision the target platform comprises a local application.

41. An article comprising: a storage medium having a plurality of machine accessible instructions, wherein when the instructions are executed by a processor, the instructions provide for receiving a special packet from a manageability server, wherein the special packet generates an interrupt that transitions a processor of a hung computer into a management mode, the management mode enabling the hung computer to reset itself, the management mode method comprising instructions for determining whether the special packet indicates a reset request event;
if the special packet indicates a reset request event, receiving a reset request packet, wherein the reset request packet includes a secure code;
comparing the secure code with a stored secure code; and
if the secure code is valid, resetting the hung computer.

42. The article of claim 41, further comprising instructions for continuing a mode of operation performed prior to the interrupt, if the secure code is invalid.

43. The article of claim 41, wherein the special packet comprises a Wake-on-LAN (local-area network) packet.

44. The article of claim 41, wherein the secure code comprises a one-time pad (OTP).

45. The article of claim 44, wherein the one-time pad is encrypted with a secret key prior to being received, and wherein instructions for comparing the secure code with the stored secure code comprises instructions for decrypting the secure code to obtain the secret key.

46. The article of claim 41, wherein the hung computer comprises a computer in which a foreground operating system is non-responsive.

47. The article of claim 46, wherein a computer comprises one of a workstation, a desktop computer, a laptop computer, and a server computer.

48. The article of claim 41, wherein instructions for resetting the hung computer comprises instructions for sending a byte sequence for asserting a reset signal from an input/output port of a circuit to the processor, wherein the reset signal re-launches an operating system of the hung computer into a working environment.

49. The article of claim 48, wherein the circuit comprises an application specific integrated circuit (ASIC).

49. The article of claim 41, wherein instructions for resetting the hung computer further comprises instructions for recording the reset event in a persistent storage to generate an error log.
